(19) United States
(12) Patent Application Publication
(10) Pub. No.: US 2024/0312001 A1
(43) Pub. Date: Sep. 19, 2024

(54) METHOD FOR GENERATING A LAYER THICKNESS VARIATION PROFILE OF A SURFACE LAYER OF A SUBSTRATE

(71) Applicant: confovis GmbH, Jena (DE)

(72) Inventors: Frank Thielert, Jena (DE); Nico Bergemann, Jena (DE)

(21) Appl. No.: 18/607,778

(22) Filed: Mar. 18, 2024

(30) Foreign Application Priority Data
Mar. 17, 2023 (DE) 10 2023 106 815.6

(51) Int. Cl. G06T 7/00; G01B 11/06; G06T 7/60

(52) U.S. Cl. CPC G06T 7/001; G01B 11/06; G06T 7/60; G06T 2207/20081; G06T 2207/30148

(57) ABSTRACT

A layer thickness variation profile of a surface layer of a substrate is generated by selecting a plurality of measurement fields on a substrate surface and measuring layer thicknesses of the surface layer at a plurality of measuring points in each measurement field with a measuring device. In addition, a grayscale image of the substrate surface is captured with a camera and the measurement fields are selected in the grayscale image. Grayscale value variations are determined between the grayscale values of the grayscale image present at the measuring points. Layer thickness variations are determined by calculating the difference between the layer thicknesses measured at the measuring points. The layer thickness variations determined between these measuring points are assigned to the corresponding grayscale value variations determined between these measuring points. The layer thickness variation profile of the surface layer based on the grayscale values of the grayscale image.

### CROSS-REFERENCE TO RELATED APPLICATION

This application claims the priority, under 35 U.S.C. § 119, of German Patent Application DE 10 2023 106 815.6, filed Mar. 17, 2023; the prior application is herewith incorporated by reference in its entirety.

### FIELD AND BACKGROUND OF THE INVENTION

The present invention relates to a method for creating a layer thickness variation profile of a surface layer of a substrate, by:
selecting a plurality of measurement fields on a substrate surface of the substrate; and
measuring layer thicknesses of the surface layer of the substrate at a plurality of measuring points in each of the measurement fields with a measuring device.

In the post-processing of a substrate—in particular, the grinding of a silicon wafer with a transparent layer applied thereto, such as a LiTaO₃ layer—characteristic grinding patterns form on a surface layer of the substrate. The topography of these grinding patterns, i.e., the local variation of a layer thickness of the corresponding surface layer, depends upon the process parameters of the post-processing. The corresponding topography reflects waviness or roughness of the surface layer of the substrate.

For certain applications, e.g., in the production of resonators, the waviness of the surface layer of the substrate must not exceed certain limit values in the peak-to-valley ratio, i.e., the distance between a depression and a peak in the layer thickness profile of the surface layer.

In order to be able to assess which regions of the substrate are suitable for further processing, and which regions cannot be used for further processing due to excessive surface variation, it is important to have an image which is as complete and accurate as possible of a layer thickness variation profile of the surface layer of a substrate.

To determine the layer thickness variation profile of a surface layer, it can be examined, for example, with an atomic force microscope at several points. For this purpose, measurement fields are selected on a substrate surface, and these are then scanned line-for-line.

Instead of an atomic force microscope, other measuring devices can also be used to determine a layer thickness variation profile within each of the measurement fields.

The layer thickness variation profiles determined with the corresponding measuring devices within the measurement fields are very accurate, but the measurements to be carried out are very time-consuming.

A further problem arises from the fact that the determination of a layer thickness variation profile is limited to individual measurement fields of the substrate surface—typically measurement fields of only a few square millimeters. The layer thickness variation profiles determined in each of the measurement fields thus depict only samples and convey an incomplete image of a surface structure of the substrate.

United States patent application US 2018/0347966 A1 describes a method for measuring thickness fluctuations in a first layer of a multilayer semiconductor structure. According to this method, the layer thickness of the first layer at different measuring points is measured by means of a measuring device. In addition, a grayscale image is captured of the first layer by means of a camera, based upon which grayscale image grayscale values at the previously determined measuring points are determined. The measured layer thicknesses are assigned to the corresponding grayscale values, whereby a theoretical curve can be created which comprises the grayscale values on the abscissa and the layer thickness of the first layer on the ordinate. This curve can then be used to examine further layers that correspond to the product specifications.

United States patent application US 2019/0228515 A1 describes a method for detecting defects of a substrate. In the method, a grayscale image of the substrate to be analyzed is created. Film thickness difference values which are used to evaluate the substrate are calculated on the basis of the resulting grayscale differences in the grayscale image, which show various regions of the substrate.

### SUMMARY OF THE INVENTION

It is accordingly an object of the invention to provide a method which overcomes the above-mentioned and other disadvantages of the heretofore-known devices and methods of this general type and which provides for a method which enables a rapid and at the same time reliable evaluation of a surface structure of substrate surfaces.

With the above and other objects in view there is provided, in accordance with the invention, a method for creating a layer thickness variation profile of a surface layer of a substrate, the method comprising the following steps:
capturing a grayscale image of a substrate surface of the substrate with a camera;
selecting a plurality of measurement fields on the substrate surface from regions of the grayscale image;
measuring layer thicknesses of the surface layer of the substrate with a measuring device at a plurality of measuring points in each of the measurement fields;
determining grayscale value variations between the grayscale values present at measuring points of the measurement fields of the grayscale image;
determining layer thickness variations by calculating a difference between the layer thicknesses measured at the measuring points of the measurement fields;
associating the layer thickness variations determined between the measuring points with corresponding grayscale value variations determined between the respective measuring points; and
creating the layer thickness variation profile of the surface layer based on the grayscale values of the grayscale image.

In other words, the objects of the invention are achieved by a method for creating a layer thickness variation profile of a surface layer of a substrate. In an alternatively ordered statement of the novel steps, the method comprises the following:
capturing a grayscale image of a substrate surface of the substrate with a camera;
selecting a plurality of measurement fields on the substrate surface of the substrate, wherein the plurality of measurement fields are selected from regions of the grayscale image;
determining grayscale value variations of the grayscale image between the grayscale values present at the measuring points of the measurement fields;
measuring layer thicknesses of the surface layer of the substrate at a plurality of measuring points in each of the measurement fields with a measuring device;
determining layer thickness variations by calculating the difference between the layer thicknesses measured at the measuring points of the measurement fields;
assigning the layer thickness variations determined between the measuring points to the corresponding grayscale value variations determined between these measuring points; and
creating the layer thickness variation profile of the surface layer on the basis of the grayscale values of the grayscale image.

In order to carry out the method according to the invention, first, a grayscale image of a substrate surface of the substrate is captured with a camera. The grayscale image depicts a contiguous region of the substrate surface in high detail, i.e., very high resolution. For example, the grayscale image depicts a quarter of a, for example, disk-shaped wafer. A grayscale value between 0 and 255 is assigned to each image point and/or pixel of the grayscale image.

Suitable measurement fields on the substrate surface are identified and selected on the basis of the grayscale image. Suitable measurement fields are, for example, measurement fields having a large difference in grayscale values. The suitable measurement fields are selected, for example, by an operator. For the selection of suitable measurement fields, the operator can be supported by image recognition and/or image analysis software. However, it is also possible for suitable measurement fields to be selected exclusively by machine—for example, by means of artificial intelligence.

In the measurement fields determined on the basis of the grayscale image, the layer thickness of the surface layer of the substrate is then determined at a plurality of measuring points using a measuring device. The corresponding measuring device is selected according to the definition of task, availability, desired accuracy, etc. All devices that are common in the field of layer thickness and/or roughness measurement of substrate surfaces, based upon, for example, a contacting, i.e., tactile, measuring method, such as atomic force microscopy, or based upon contactless methods, in particular, optical measurement methods from the field of confocal technology, are suitable as measuring devices.

In particularly high-resolution measuring devices, the measurement fields are typically only a few square millimeters in size—for example, 3 mm×3 mm. Accordingly, a measurement in each of the measurement fields depicts only one sample of the entire substrate surface.

Following the measurement using the measuring device, layer thickness variations between the layer thicknesses measured at the measuring points of each of the measurement fields are determined by calculating the difference.

A layer thickness profile of the surface layer of the substrate is transformed into a layer thickness variation profile. Ultimately, the absolute layer thickness does not matter when characterizing the waviness of the substrate layer. Depending upon which measuring device is used, layer thickness variation profiles are often already determined directly by the applied measurement method in each of the measurement fields. As a result of this method step, the layer thickness variation profiles there are sufficiently known for each of the measurement fields, i.e., with sufficient accuracy.

The measuring points in the measurement fields are then assigned to individual image points, i.e., pixels, of the grayscale image. Thus, a grayscale value, i.e., for example, a value between 0 and 255, is also assigned to each of the measuring points.

In a further method step, grayscale value variations are determined between the grayscale values of the grayscale image at the measuring points of each of the measurement fields.

Both layer thickness variations and grayscale value variations are thus determined between the measuring points of each of the measurement fields.

In a further method step, the layer thickness variations determined between the measuring points are assigned to the corresponding grayscale value variations determined between these measuring points.

Consequently, in a further method step, the layer thickness variation profile of the entirety of the surface layer captured in the grayscale image can be determined on the basis of the grayscale values of the grayscale image.

As a result, starting from high-resolution measurements of the layer thickness variation within the selected measurement fields, it is possible to deduce the layer thickness variation profile of the total surface layer of the substrate, shown in the grayscale image.

The method thus provides a rapid and reliable method for characterizing substrates with respect to their surface roughness, and for determining, for example, which regions of the substrate are suitable for further processing and which are not suitable for further processing due to an excessive surface roughness.

The method according to the invention can advantageously be further refined by virtue of the fact that the layer thickness variations determined between the measuring points are stored, together with the grayscale value variations determined between the corresponding measuring points, in a data set, at least one further grayscale image is captured of a further substrate surface of a further substrate, and the data set is utilized to create the layer thickness variation profile of a surface layer of the further substrate on the basis of grayscale values of the further grayscale image of the further substrate surface of the further substrate.

For example, the substrate surface of a first substrate within the plurality of measurement fields is examined in order to obtain an assignment between the layer thickness variation and the associated grayscale value variation. The assignment is stored in a data set. For example, the assignment can be stored in tabular form and/or in the form of a function in the data set. The data set is then used to evaluate directly the grayscale image captured from a further substrate surface of a further substrate. This makes it possible to characterize substrate surfaces precisely with respect to their surface roughness, without having to carry out a layer thickness measurement with a corresponding measuring device on the further substrate.

When the layer thickness variations determined between the measuring points, together with the grayscale value variations determined between the corresponding measuring points, are stored in a data set, it proves to be particularly advantageous if the layer thickness variations contained in the data set are assigned to different layer thickness variation ranges, and the individual layer thickness variation ranges are assigned to at least one of the grayscale value variations, respectively.

The assignment of the layer thickness variations to different layer thickness variation ranges can take place, for example, in the form of a layer thickness variation scale which is divided into layer thickness variation ranges, i.e., intervals.

The layer thickness variation scale does not necessarily have to be linear, i.e., it does not necessarily have to be divided into equal intervals. By assigning the layer thickness variations contained in the data set to a discrete quantity of layer thickness variation ranges, it is easier to assign the layer thickness variations to the grayscale value variations, which likewise typically assume only discrete values.

When the layer thickness variations determined between the measuring points are stored together with the grayscale value variations determined between the corresponding measuring points in a data set, the method according to the invention can be further refined particularly advantageously if a plurality of the data sets which have been determined on different substrates are stored in a data packet and linked, wherein the data packet is used to train an artificial intelligence which creates the corresponding layer thickness variation profile solely from the grayscale values or the grayscale value variations of grayscale images captured on further substrates.

The method according to the invention can be improved in that, when selecting the plurality of measurement fields, regions in a substrate center and/or on a substrate edge of the substrate are not taken into account. These regions are, for production reasons, not meaningful, and/or cannot be used further anyway, and can falsify the impression of the substrate surface. Since a robust correlation between the grayscale value variations and the layer thickness variations must be present in order to achieve a particularly high quality of the layer thickness variation profiles determined by the method according to the invention, it is therefore advantageous if regions in the substrate center and/or on the substrate edge, and/or in similarly critical regions of the substrate surface, are excluded.

After the exclusion of regions in the substrate center and/or on the substrate edge, it proves to be particularly advantageous for the method according to the invention if the plurality of measurement fields are selected in such a way as to find the grayscale differences in the measurement fields that are the highest in comparison to other regions of the substrate surface. “Highest grayscale differences” means that, based upon a grayscale range of 0 to 255, differences between the grayscale values amount to at least 10 gray shades, preferably at least 15 gray shades, and particularly preferably at least 20 gray shades, in the grayscale image. At the same time, the measurement fields in regions of the highest grayscale differences typically also have the greatest distances between peaks and valleys of a substrate surface. By employing wide value ranges with respect to the layer thickness variation, i.e., with respect to the corresponding grayscale value variation, the regions of highest grayscale differences are particularly well suited for calibration of the method according to the invention.

The accuracy of the method according to the invention can further be increased in that the plurality of measurement fields is selected such that they partially overlap. Due to partially overlapping measurement fields, no layer thickness variations and/or grayscale value variations in edge regions of adjacent, non-overlapping measurement fields are lost. Furthermore, abrupt variations from one measurement field to the next can be better detected in this way.

In a particularly advantageous embodiment of the method according to the invention, the surface layer is transparent, and the measuring device is an optical measuring device.

For example, in this case, a silicon substrate coated with a lithium tantalate (LiTaO₃) layer is used as the substrate. The LiTaO₃ layer forms a transparent surface layer of the substrate. The layer thickness of this surface layer is determined, for example, using an interferometer, a reflectometer, a refractometer, or a scattered light method.

Other features which are considered as characteristic for the invention are set forth in the appended claims.

Although the invention is illustrated and described herein as embodied in a method for creating a layer thickness variation profile of a surface layer of a substrate, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a schematic plan view onto a substrate of which a layer thickness variation profile will be determined according to one embodiment of the method according to the invention;

FIG. 2 is a schematic view of a grayscale image captured from a substrate surface of the substrate of FIG. 1;

FIG. 3 schematically shows a layer thickness profile;

FIG. 4 schematically shows a layer thickness variation profile of the layer thickness profile of FIG. 3;

FIG. 5 schematically shows a grayscale value profile;

FIG. 6 schematically shows the grayscale value variation profile of the grayscale value profile of FIG. 5; and

FIG. 7 schematically shows a normalized grayscale variation profile of the grayscale variation profile of FIG. 6 linked to a normalized layer thickness variation profile of the layer thickness variation profile of FIG. 4.

### DETAILED DESCRIPTION OF THE INVENTION

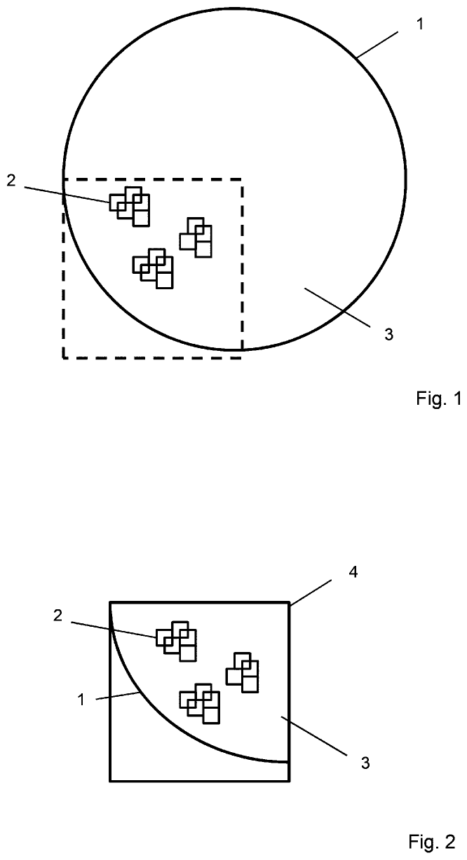

Referring now to the figures of the drawing in detail and first, in particular, to FIG. 1 thereof, there is shown a substrate 1 with a surface layer. The illustration is a plan view, i.e., the view is onto a substrate surface 3 of the substrate 1.

The substrate 1 shown in FIG. 1 is a disk-shaped silicon substrate on which the surface layer is formed by a transparent LiTaO₃ (lithium tantalate) layer.

A grinding of the LiTaO₃ layer during a post-processing of the substrate 1 has left on its substrate surface 3 an approximately radially symmetrical grinding pattern. Accordingly, a layer thickness of the surface layer varies.

According to the invention, there are now multiple possibilities for determining a layer thickness variation profile of the surface layer of the substrate 1. In each case, a grayscale image 4 is captured of the substrate surface 3, or at least a portion of the substrate surface 3.

In FIG. 1, the part of the substrate surface 3 where the grayscale image 4 is captured is schematically denoted by a dashed rectangle. The grayscale image 4 captured of this part of the substrate surface 3 is shown separately in FIG. 2.

As can be seen in FIGS. 1 and 2, approximately one quarter of the substrate surface 3 of the substrate 1 to be examined is captured in the grayscale image 4. Depending upon the camera used and according to the type and shape of the substrate 1 to be examined, an image detail of the substrate surface 3 can also be selected separately as a grayscale image 4 and, for example, can contain the entire substrate surface 3.

Suitable measurement fields 2 are selected on the basis of the grayscale image 4. In the selection of suitable measurement fields 2, regions on a substrate edge and a substrate center of the substrate 1 are not taken into account in the present case, since they are generally less informative.

In the selection of the measurement fields 2, in particular regions of the substrate surface 3 are used which have the highest grayscale value differences, and at the same time allow a representative sample of the layer thickness variation profile to be expected. In the present case, regions were identified in the grayscale image in which the grayscale values were between 174 and 186.

A further criterion for selecting suitable measurement fields 2 is that the selected measurement fields 2 are simple to measure with a measuring device for determining the layer thickness d.

In the present case, the measurement fields 2 are selected by a human operator. When selecting suitable measurement fields, the operator can also be supported by image recognition and/or image evaluation software. In a further embodiment of the method according to the invention, suitable measurement fields are selected exclusively by means of artificial intelligence.

As shown in FIGS. 1 and 2, the measurement fields 2 partially overlap and thus form a cluster which covers a larger contiguous region of the substrate surface 3 without gaps.

The measurement fields 2 have a plurality of measuring points whose position on the substrate surface 3 is indicated in the present case by coordinates x, y of a Cartesian coordinate system. The position of the measuring points can also be detected and indicated by a different coordinate system, e.g., a polar coordinate system.

Within the measurement fields 2, layer thicknesses d are then measured at the individual measuring points with a measuring device. In the present case, the layer thickness d of the transparent surface layer of the substrate 1 is measured using a reflectometer.

The layer thicknesses d measured at the measuring points, at least for the region of the substrate surface 3 in which each of the measurement fields 2 is located, provide a high-resolution and sufficiently accurate layer thickness profile of the surface layer.

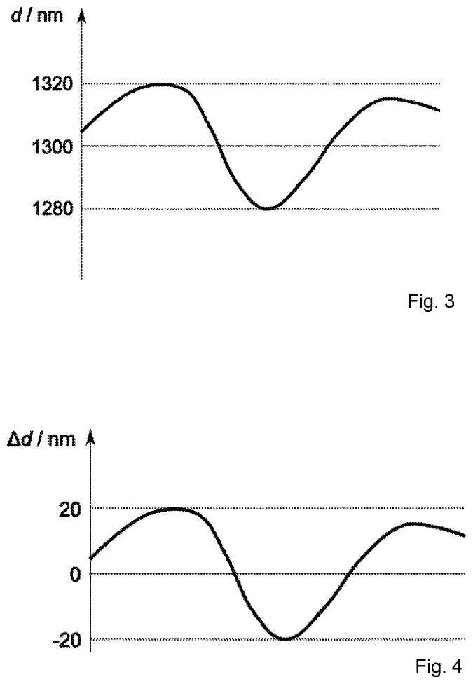

Such a layer thickness profile is shown schematically in FIG. 3. The diagram shown in FIG. 3 depicts the measured layer thickness d of the surface layer in nanometers as a function of a location of the measuring point.

A layer thickness variation profile, which is shown schematically in FIG. 4, is determined from the layer thickness profile by calculating a difference.

Depending upon which measuring device is used, the layer thickness variation profiles may already be determined by this process alone. In this case, either a conversion of layer thicknesses d into layer thickness variations already takes place directly during the measurement, or an underlying measuring method initially provides layer thickness differences, i.e., layer thickness variations, instead of absolute layer thicknesses. This applies, for example, to tactile measuring systems for determining surface roughness.

Since the measurement fields 2 are also contained in the grayscale image 4, i.e., the regions on the substrate surface 4 in which a layer thickness variation profile has been measured or determined are also found in the grayscale image 4, a grayscale value g between 0 and 255 can also be assigned to each of the measuring points.

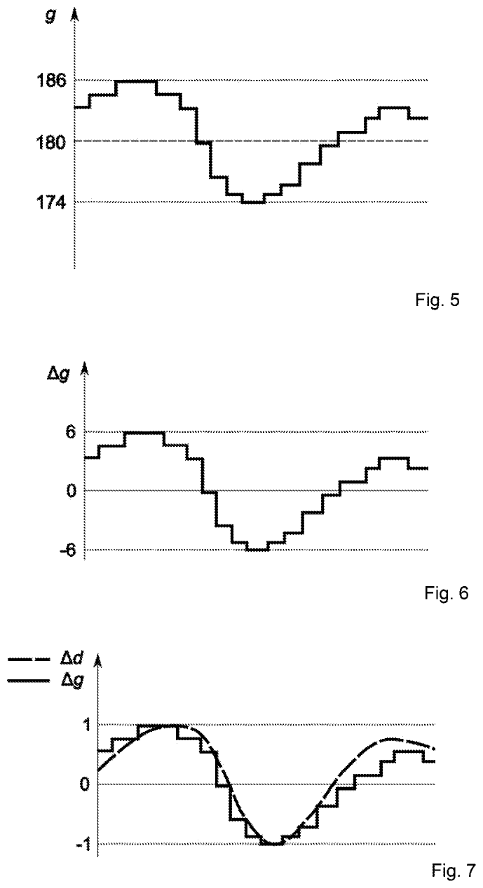

The location-dependent grayscale values g can be compiled as a grayscale value profile of the surface layer of the substrate 1, as shown schematically in FIG. 5.

In a further step of the method according to the invention, grayscale value variations of the grayscale image 4 are determined from the grayscale values g present between the measuring points of each of the measurement fields 2. This provides an additional grayscale value variation profile for the measurement fields 2, as shown schematically in FIG. 6.

It is thus possible to assign the layer thickness variations determined between the measuring points to grayscale value variations determined between these measuring points, as is illustrated in FIG. 7.

In the diagram shown in FIG. 7, the layer thickness variation profiles originating from measurements with the measuring device, together with the associated grayscale value variation profile determined from the grayscale image 4, are shown, wherein values of the layer thickness variation profile and of the grayscale value variation profile are normalized.

With this assignment, it is possible to create a layer thickness variation profile of the entire substrate surface 3 of the substrate 1 captured in the grayscale image 4, which is referred to below as the first substrate 1.

In the present case, the layer thickness variations determined between the measuring points are stored in a data set together with the grayscale value variations determined between the corresponding measuring points.

With the aid of this data set, a layer thickness variation profile of a surface layer of a further substrate can be determined. The further substrate is basically constructed like the first substrate 1, but can have other surface properties—in particular, a different surface roughness. A further grayscale image is captured of the substrate surface of the further substrate, and the data set created on the basis of the first substrate 1 is applied thereto.

Likewise, the data set can be applied to grayscale images 4 of other regions of the substrate surface 3 shown in FIG. 1. Thus, in the example shown in FIG. 1, the rest of the substrate surface 3 can be captured with three further grayscale images 4, and a complete layer thickness variation profile of the entire substrate surface 3 can be determined by applying the data set.

In the present case, a plurality of the data sets which have been determined on different substrates are also stored and linked in a data packet. The continuously growing data packet is used to train an artificial intelligence which creates the layer thickness variation profiles solely from the grayscale values g of grayscale images of further substrates. That is to say, after the artificial intelligence machine is trained, it can, on the basis of grayscale image data only, undertake a comprehensive characterization of a topography of the surface layer—in the present case, the transparent LiTaO₃ layer. The accuracy and reproducibility of the method according to the invention is continuously increased by additional reference data and a (preferably continuously) growing data pool.

The possibilities for carrying out the method according to the invention described by way of example with reference to FIGS. 1 to 7 can be combined with one another in many ways. The same applies to individual method steps and their sequence. The method according to the invention can also be applied to a variety of different substrate surfaces and surface layers.

In further embodiments of the method according to the invention, image data of the grayscale images and/or measurement data determined with the measuring device are filtered with a bandpass filter before an evaluation in order to suppress noise and macroscopic variations.

It can also be advantageous to carry out a principal component analysis for each measurement field in order to reduce a dimensionality of 2-D to 1-D.

In addition, the method according to the invention can also be applied, by virtue of an additional calibration step, for determining an absolute layer thickness of a surface layer of a substrate. For this purpose, a correlation between grayscale values and absolute layer thicknesses of the surface layer is produced, for example, by selected measurements using a reflectometer or another common measuring device for determining layer thicknesses.

In a further embodiment of the method according to the invention, measurements with the reflectometer for determining the layer thickness are validated by measurements with further measuring devices. For example, the measurements using the reflectometer used in the present case are validated by confocal microscopy.

1. A method for creating a layer thickness variation profile of a surface layer of a substrate, the method comprising the following steps:
capturing a grayscale image of a substrate surface of the substrate with a camera;
selecting a plurality of measurement fields on the substrate surface from regions of the grayscale image;
measuring layer thicknesses of the surface layer of the substrate with a measuring device at a plurality of measuring points in each of the measurement fields;
determining grayscale value variations between the grayscale values present at measuring points of the measurement fields of the grayscale image;
determining layer thickness variations by calculating a difference between the layer thicknesses measured at the measuring points of the measurement fields;
associating the layer thickness variations determined between the measuring points with corresponding grayscale value variations determined between the respective measuring points; and
creating the layer thickness variation profile of the surface layer based on the grayscale values of the grayscale image.

2. The method according to claim 1, which comprises:
storing in a data set the layer thickness variations determined between the measuring points together with the grayscale value variations determined between the corresponding measuring points;
capturing at least one further grayscale image of a further substrate surface of a further substrate; and
utilizing the data set to create the layer thickness variation profile of a surface layer of the further substrate on a basis of grayscale values of the further grayscale image of the further substrate surface of the further substrate.

3. The method according to claim 2, which comprises assigning the layer thickness variations contained in the data set to different layer thickness variation ranges, and assigning the individual layer thickness variation ranges to at least one of the grayscale value variations, respectively.

4. The method according to claim 2, which comprises storing a plurality of the data sets which have been determined for different substrates and linking the plurality of data sets in a data packet, and using the data packet to train an artificial intelligence model which creates the layer respective thickness variation profile solely from the grayscale values or the grayscale value variations of grayscale images captured from further substrates.

5. The method according to claim 1, which comprises, in the step of selecting the plurality of measurement fields, not taking into account regions in a substrate center and/or on a substrate edge of the substrate.

6. The method according to claim 5, wherein the step of selecting the plurality of measurement fields comprises selecting measurement fields in which grayscale contrasts are highest in comparison with other regions of the substrate surface.

7. The method according to claim 1, wherein the step of selecting the plurality of measurement fields comprises selecting measurement fields that partially overlap.

8. The method according to claim 1, wherein the surface layer is transparent, and the measuring device is an optical measuring device.
